(19) United States
(12) Patent Application Publication
(10) Pub. No.: US 2024/0244813 A1
(43) Pub. Date: Jul. 18, 2024

(54) TAPE FEEDER SETUP SYSTEM

(71) Applicant: FUJI CORPORATION, Aichi (JP)

(72) Inventor: Yoshiharu TANIZAWA, Toyota-shi (JP)

(73) Assignee: FUJI CORPORATION, Chiryu (JP)

(21) Appl. No.: 18/558,488

(22) PCT Filed: May 25, 2021
(86) PCT No.: PCT/JP2021/019722

§ 371 Date: Nov. 1, 2023

(51) Int. Cl. H05K 13/04

(52) U.S. Cl. CPC H05K 13/0419

(57) ABSTRACT

A tape feeder setup system includes a loading table on which a tape feeder is placed, the tape feeder having a drive mechanism configured to feed a carrier tape accommodating multiple components to be mounted on a board from a reel in a predetermined supply direction and supplying the component, a determination section configured to determine whether the carrier tape is automatically returned in a reverse direction of the supply direction based on a use plan in a future of the component and an estimable use frequency in the future of the component for the tape feeder placed on the loading table as a target, and a control section configured to cause the drive mechanism of the tape feeder to return the carrier tape in the reverse direction in a case where the determination section determines that the carrier tape is automatically returned in the reverse direction.

### TECHNICAL FIELD

The description relates to a tape feeder setup system that assists or supports setup change of a tape feeder used in a component mounter.

### BACKGROUND ART

A technique for mass-producing board products by performing board work on a board on which a circuit pattern is formed is widespread. Furthermore, it is common to form a board work line by arranging multiple board work machines for performing the board work. As a representative example of a board work machine, there is a component mounter that performs mounting work of a component. Many component mounters use a tape feeder that feeds out a carrier tape accommodating multiple components from a reel. When changing the type of board to be produced, the setup change for multiple tape feeders is required in many cases. Patent Literature 1 discloses an example of a technique related to a setup change of a tape feeder of this type.

The tape feeder setup system disclosed in Patent Literature 1 includes a loading table on which a tape feeder is placed, a use schedule discrimination section configured to determine whether there is a use schedule of a component supplied from the tape feeder, and a control section configured to cause a drive mechanism of the tape feeder to return the carrier tape in a reverse direction in a case where there is no use schedule. With this configuration, an engaged state of the carrier tape with the tape feeder can be released without manual work of an operator, and the reel can be removed with good reliability and without requiring a large amount of labor of the operator.

### PATENT LITERATURE

Patent Literature 1: International Publication No. WO 2018/109793

### SUMMARY OF THE INVENTION

### Technical Problem

However, according to the technique of Patent Literature 1, it is possible to reduce the labor for removing the reel from the tape feeder by returning the carrier tape accommodating the component not scheduled to be used in the reverse direction. However, in a case where the reel is used again, double labor is generated for the resetting work of the reel and the reloading work of the carrier tape. Therefore, the labor is reduced by not removing the reel to be used in the near future even when there is no use schedule. On the other hand, a tape feeder in which a reel not used for a long period is set cannot be used for the production. As a result, the use efficiency of the owned tape feeders the number of which is limited decreases, or a problem occurs in the production of board products. Therefore, in determining whether the reel is required to be removed, it is desirable to take into account not only whether there is a next use schedule but also the possibility that the reel is used in the near future.

Therefore, an issue to be solved of the description is to provide a tape feeder setup system capable of appropriately determining whether a reel is required to be removed in consideration of not only a use plan in the future of a component but also a use frequency in the future, and reliably reducing labor of setup change.

### Solution to Problem

The description discloses a tape feeder setup system including a loading table on which a tape feeder is placed, the tape feeder having a drive mechanism configured to feed a carrier tape accommodating multiple components to be mounted on a board from a reel in a predetermined supply direction and supplying the component, a determination section configured to determine whether the carrier tape is automatically returned in a reverse direction of the supply direction based on a use plan in a future of the component and an estimable use frequency in the future of the component for the tape feeder placed on the loading table as a target, and a control section configured to cause the drive mechanism of the tape feeder to return the carrier tape in the reverse direction in a case where the determination section determines that the carrier tape is automatically returned in the reverse direction.

### Advantageous Effect of the Invention

In the disclosed tape feeder setup system, it is determined whether carrier tape is automatically returned in the reverse direction based on the use plan in the future and the use frequency in the future of the component for the tape feeder placed on the loading table as a target. Therefore, it is possible to select only a carrier tape accommodating a component that is not scheduled to be used, has a low use frequency in the future, and has a low possibility of being used in the near future, and to return the carrier tape in the reverse direction. With this configuration, since the engaged state of the carrier tape with the tape feeder is automatically released, the labor of the setup change for removing the reel is reduced. On the other hand, a carrier tape accommodating a component which has a high use frequency in the future and is likely to be used in the near future even when the component is not scheduled to be used is maintained in a loaded state into the tape feeder. With this configuration, double labor for the resetting work of the reel and the reloading work of the carrier tape in the near future is not necessary, and the labor of the setup change is reduced.

### BRIEF DESCRIPTION OF DRAWINGS

FIG. 1 is a plan view of a component mounter to which a tape feeder setup system according to an embodiment is applied.

FIG. 2 is a side view of a tape feeder and a reel.

FIG. 3 is a diagram schematically illustrating a configuration of the tape feeder setup system according to the embodiment.

FIG. 4 is a perspective view of an external setup station.

FIG. 5 is a block diagram illustrating a control configuration of the tape feeder setup system.

FIG. 6 is a diagram of a production flow conceptually illustrating a step of producing multiple types of boards.

FIG. 7 is an operation flow diagram illustrating an operation of the tape feeder setup system in a setup step.

FIG. 8 is a diagram of a display example in which a display section displays setup work required in the setup step.

FIG. 9) is a table schematically describing an operation of a storage section.

FIG. 10 is an operation flow diagram illustrating an operation of the tape feeder setup system in a post-setup step.

FIG. 11 is a diagram of a display example in which the display section displays setup work required in the post-setup step.

FIG. 12 is a table schematically describing an operation of a release section.

### DESCRIPTION OF EMBODIMENTS

### 1. Configuration of Component Mounter 1

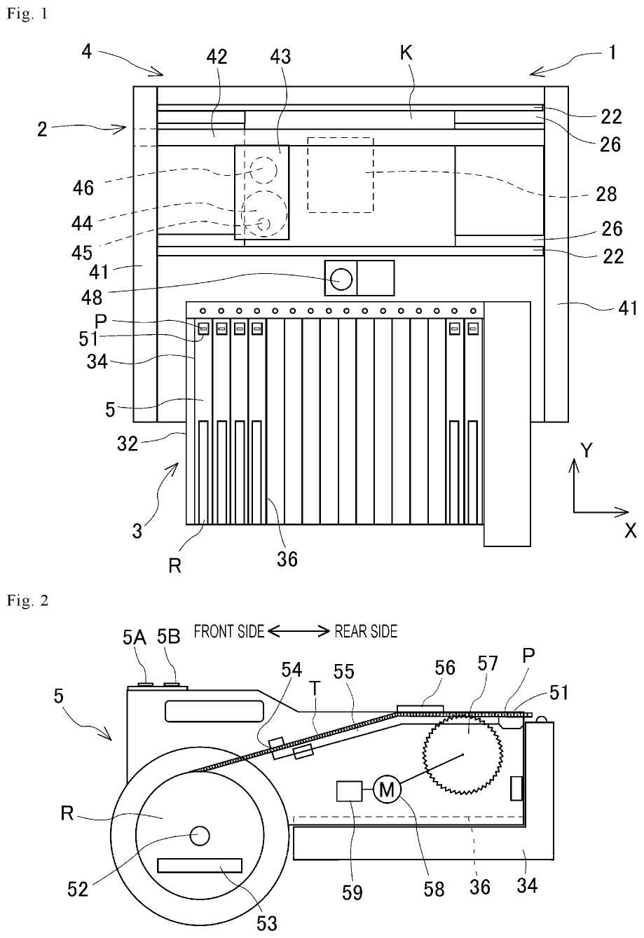

First, a configuration of component mounter 1 to which a tape feeder setup system according to an embodiment is applied will be described with reference to FIG. 1. Component mounter 1 is installed in a board work line for mass-producing board products. As illustrated in FIG. 1, component mounter 1 includes board conveyance section 2, component supply section 3, component transfer section 4, and the like. The left-right direction in FIG. 1 is an X-axis direction in which board K is conveyed, and the up-down direction in FIG. 1 is a Y-axis direction corresponding to the front-rear direction of component mounter 1.

Board conveyance section 2 conveys board K on which the circuit pattern is formed. Board conveyance section 2 includes a pair of guide rails 22, a pair of conveyor belts 26, and clamp device 28. The pair of guide rails 22 are disposed in parallel with each other with a space therebetween. The pair of conveyor belts 26 are formed of annular belt members on which boards K can be placed. Each of the pair of conveyor belts 26 is rotationally driven along guide rail 22 and conveys board K in the X-axis direction. Clamp device 28 is disposed below a mounting execution position set at substantially the center in the X-axis direction. Clamp device 28 pushes up board K from below, clamps board K between clamp device 28 and guide rail 22, and positions board K.

Component supply section 3 supplies component P to be mounted on board K. As illustrated in FIG. 1, component supply section 3 is disposed on the front side of component mounter 1. Component supply section 3 includes loading table 32, feeder holding portion 34, multiple tape feeders 5, and the like. Loading table 32 is detachably attached to component mounter 1. Loading table 32 is formed in, for example, a wheeled platform shape. A label (not illustrated) representing a loading table ID for specifying an individual is attached to loading table 32.

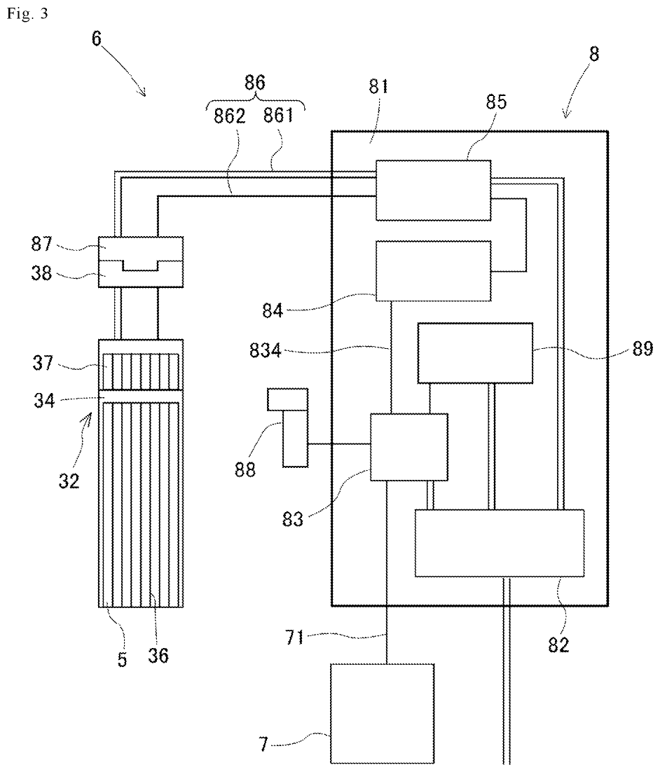

Feeder holding portion 34 has a substantially rectangular shape and is disposed above loading table 32. Feeder holding portion 34 includes multiple slots 36 arranged side by side in the X-axis direction, extending in the Y-axis direction, and parallel to each other. Each of slots 36 is assigned slot numbers different from each other. As illustrated in FIG. 3, sub-connector 37 provided for each slot 36 is arranged in the rear part of feeder holding portion 34. Furthermore, multiple sub-connectors 37 are connected in parallel to one main connector 38.

Each of multiple tape feeders 5 is detachably inserted into slot 36 of feeder holding portion 34 and placed thereon. Therefore, the slot number indicates an arrangement position of each of multiple tape feeders 5. When tape feeder 5 is inserted into slot 36, the feeder side connector is automatically connected to sub-connector 37. As a result, feeder control section 59 described later is communicably connected to main connector 38. Each tape feeder 5 pulls out carrier tape T (refer to FIG. 2) from reel R held on the front side, feeds carrier tape T to component supply position 51 close to the rear end, and supplies component P at component supply position 51. The detailed configuration of tape feeder 5 will be described later.

Component transfer section 4 picks up component P from component supply position 51 and transfers component P to a predetermined mounting position on board K. Component transfer section 4 includes a pair of guide rails 41. Y-axis slider 42. X-axis slider 43, mounting head 44, board camera 46, and the like. The pair of guide rails 41 are disposed on both left and right sides of component mounter 1 so as to be separated from each other, and extend in the Y-axis direction to be parallel to each other. Y-axis slider 42 is formed of a member elongated in the X-axis direction, and is mounted across the pair of guide rails 41. Y-axis slider 42 is driven by a Y-axis servo motor (not illustrated) to move in the Y-axis direction.

X-axis slider 43 is mounted on Y-axis slider 42. X-axis slider 43 is driven by an X-axis servo motor (not illustrated) provided on Y-axis slider 42 to move in the X-axis direction. Mounting head 44 is attached to the lower side of X-axis slider 43. Mounting head 44 moves in two horizontal directions (X-Y directions) as Y-axis slider 42 and X-axis slider 43 move. Mounting head 44 detachably includes suction nozzle 45 that picks up component P using negative pressure. Suction nozzle 45 moves to component supply position 51 of component supply section 3 to pick up component P. and moves to a predetermined mounting position on board K to mount component P. Mounting head 44 may include multiple suction nozzles 45. In addition, mounting head 44 may include a component mounting tool that clamps component P instead of suction nozzle 45.

Board camera 46 is attached to the rear side of lower mounting head 44 of X-axis slider 43. Board camera 46 images a positioned fiducial mark of board K from above to acquire image data. The image data is subjected to image processing to obtain accurate position information on board K. This position information is used for position control when suction nozzle 45 mounts component P.

In addition, part camera 48 is attached between board conveyance section 2 and component supply section 3. Part camera 48 images component P picked up by suction nozzle 45 from below to acquire image data. The image data is subjected to image processing to obtain shape information on component P and information on the pickup position and the rotation posture. The shape information is used, for example, for determining whether the component is correct or incorrect. In addition, the information on the pickup position and the rotation posture is used for the position control and the posture control when suction nozzle 45 mounts component P.

### 2. Detailed Configuration of Tape Feeder 5

Next, a detailed configuration of tape feeder 5 will be described with reference to FIG. 2. Tape feeder 5 is formed into a thin type having a small width dimension. As illustrated in FIG. 2, tape feeder 5 includes reel holding shaft 52 for holding reel R near the front side. Reel holding shaft 52 is engaged with a center hole of reel R to detachably and rotatably hold reel R. Reel R is a rotating body around which carrier tape T accommodating multiple components P is wound. Carrier tape T is provided with a large number of cavity portions (not illustrated) for accommodating components P one by one. Furthermore, carrier tape T is provided with a large number of sprocket holes on one side in the tape width direction.

Label 53 representing a reel ID for specifying an individual of reel R is attached to a side surface of reel R. The reel ID includes information specifying the type of component P or is stored in association with the information specifying the type of component P. Label 53 is created by printing, for example, a barcode, a two-dimensional code, a character string, or the like.

Tape feeder 5 includes tape insertion port 54 and guide rail 55 as a conveyance path for feeding carrier tape T. Tape insertion port 54 is disposed at the rear upper position of reel R held by reel holding shaft 52. Guide rail 55 extends in a predetermined supply direction, in other words, extends from tape insertion port 54 to component supply position 51. In addition, tape peeling mechanism 56 is provided on the front side of component supply position 51 of guide rail 55. Tape peeling mechanism 56 peels off the cover tape of carrier tape T to expose component P accommodated in the cavity portion of the base tape so that suction nozzle 45 can pick up component P.

In addition, tape feeder 5 includes sprocket 57 and drive motor 58 as drive mechanisms for feeding carrier tape T. Sprocket 57 is rotatably supported between component supply position 51 and tape peeling mechanism 56. The teeth of sprocket 57 pass through holes formed in guide rail 55 and engage with sprocket holes of carrier tape T. Drive motor 58 is connected to a rotary shaft of sprocket 57. Drive motor 58 rotates forward to drive sprocket 57 in a forward direction of rotation so as to feed carrier tape T in a predetermined supply direction. In addition, drive motor 58 reversely rotates to drive sprocket 57 in a reverse direction of rotation so as to return carrier tape T in the reverse direction of the supply direction. The operation and stop of drive motor 58 and switching between forward rotation and reverse rotation are controlled by feeder control section 59.

A leading edge of carrier tape T is inserted into tape insertion port 54 and fed along guide rail 55 by the loading work of an operator. After the leading edge of carrier tape T reaches sprocket 57 and the teeth of sprocket 57 are engaged with the sprocket holes of carrier tape T, carrier tape T is fed by drive motor 58. Carrier tape T can be returned in the reverse direction by being appropriately cut after passing through component supply position 51.

Feeder control section 59 is communicably connected to a host control section (not illustrated) of component mounter 1, and performs bidirectional information transmission. Feeder control section 59 controls drive motor 58 according to a command from the host control section. In addition, feeder control section 59 holds information on a feeder ID for specifying an individual of tape feeder 5. Furthermore, feeder control section 59 holds the reel ID of set reel R and the feeder ID in association with each other. A label (not illustrated) representing the feeder ID is attached to the case of tape feeder 5.

In addition, tape feeder 5 includes operation switch 5A and display section 5B at the upper front part. Operation switch 5A and display section 5B are electrically connected to feeder control section 59. Operation switch 5A includes a feed switch for feeding carrier tape T in the supply direction and a return switch for returning carrier tape T in the reverse direction. Feeder control section 59 controls drive motor 58 according to the operation of operation switch 5A in a case where the operation of operation switch 5A is enabled without receiving a command from the host control section.

When reel R is removed from tape feeder 5 in the setup change, in an engaged state where the teeth of sprocket 57 are engaged with the sprocket holes of carrier tape T, carrier tape T cannot be wound around reel R. and reel R cannot be removed. Therefore, the operator releases the engaged state by pressing the return switch of operation switch 5A to return carrier tape T in the reverse direction. As a result, carrier tape T can be manually wound, and reel R can be removed.

Display section 5B includes, for example, multiple display lamps, and is not limited to this. In the embodiment, display section 5B is configured by a combination of three display lamps, that is, a green lamp, an orange lamp, and a red lamp. Display section 5B performs display based on a lighting state, a blinking state, and a non-lighting state of each display lamp. The display content of display section 5B is, for example, a current state of tape feeder 5, an abnormality item when an abnormality occurs, or the like.

### 3. Configuration of Tape Feeder Setup System 6

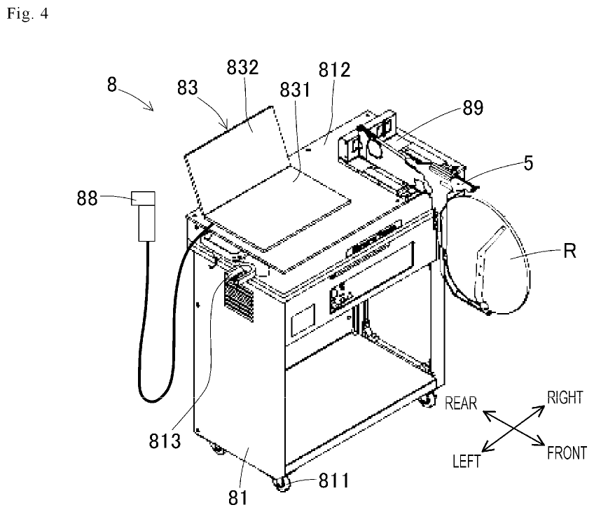

Next, a configuration of tape feeder setup system 6 according to the embodiment will be described with reference to FIGS. 3 and 4. Tape feeder setup system 6 assists or supports a setup change such as work of attaching and detaching tape feeder 5 to and from loading table 32 and work of attaching and detaching reel R to and from tape feeder 5. In the embodiment, tape feeder setup system 6 operates with loading table 32 removed from component mounter 1 as a target in the external setup area provided separately from the board work line on which component mounter 1 is installed. The configuration is not limited to this, and tape feeder setup system 6 may operate with loading table 32 attached to component mounter 1 as a target. As illustrated in FIG. 3, tape feeder setup system 6 includes host computer 7, external setup station 8, loading table 32 removed from component mounter 1, and the like.

Host computer 7 manages a production plan of board K using one or multiple component mounters 1, an operation state of component mounter 1, a production state of board K, a supply state of component P, a production result of board K. and the like. Host computer 7 is communicably connected to personal computer 83 provided in external setup station 8 via LAN 71 or the like. Therefore, host computer 7 and personal computer 83 share a lot of information via communication.

As illustrated in FIG. 4, external setup station 8 is formed in a wheeled platform shape movable in the external setup area. External setup station 8 includes housing 81, power tap 82, personal computer 83, communication unit 84, control box 85, connector 87, reel setting stand 89, and the like. Housing 81 is formed in a box shape, and includes multiple casters 811 for movement at the lower part. Power tap 82 is connected to an original power supply and supplies power of, for example, AC 100 volts. Specifically, power tap 82 supplies power to personal computer 83 and reel setting stand 89. Furthermore, power tap 82 supplies power to tape feeder 5 on loading table 32 via control box 85, harness 86, and connector 87. In FIG. 3, the power supply system is illustrated by double lines.

Personal computer 83 is disposed on the left side of upper surface 812 of housing 81. Personal computer 83 includes operation section 831 such as a keyboard and a mouse through which the operator performs an input operation, display section 832 such as a liquid crystal display through which the operator visually recognizes, and central processing section 833 that performs arithmetic control. Personal computer 83 is communicably connected to communication unit 84 via USB cable 834 or the like. Furthermore, communication unit 84 is communicably connected to control box 85. Control box 85 is connected to connector 87 via harness 86 including power supply line 861 and communication line 862. Control box 85 has the functions of a power relay and a communication relay. Control box 85 may include an operation switch for switching between execution and stop of the relay function.

Connector 87 is fitted to main connector 38 provided in feeder holding portion 34 of loading table 32. As described above, main connector 38 is connected in parallel to multiple sub-connectors 37 provided for each slot 36 via the harness for branching. Therefore, each of feeder control sections 59 of multiple tape feeders 5 and personal computer 83 are communicably connected to each other. In the embodiment, loading table 32 is not attached to or detached from external setup station 8, but is communicably connected to personal computer 83. The configuration is not limited to this, and the configuration may be configured such that loading table 32 is attached to external setup station 8, and each of feeder control sections 59 and personal computer 83 are communicably connected to each other.

In addition, barcode reader 88 is attached to personal computer 83. Barcode reader 88 is operated by the operator and reads label 53 representing each of an operation table ID, the feeder ID, and the reel ID described above. Furthermore, barcode reader 88 transmits the read ID information to personal computer 83. Barcode reader 88 is stored by being put on holder 813 provided on the upper part of the left side surface of housing 81 except for the time of use.

Reel setting stand 89 is disposed on the right side of upper surface 812 of housing 81. Reel setting stand 89 is a position where tape feeder 5 placed on feeder holding portion 34 is set up. In other words, reel setting stand 89 is a position for performing the setup work of setting reel R on tape feeder 5. Reel setting stand 89 includes a slot and a sub-connector having the same shape as that of feeder holding portion 34, and is formed such that multiple tape feeders 5 can be placed thereon. In addition, feeder control section 59 of tape feeder 5 placed on reel setting stand 89 and personal computer 83 are communicably connected to each other. Unlike loading table 32, since reel setting stand 89 ensures a large work space on both sides of tape feeder 5, the setting work of reel R and the loading work of carrier tape T are facilitated.

### 4. Configuration of Control of Tape Feeder Setup System 6

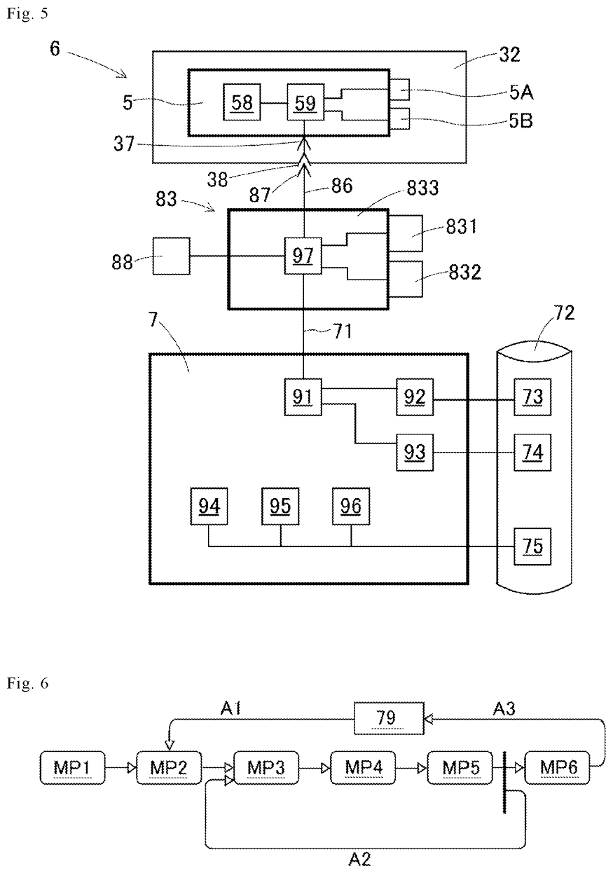

Next, a control configuration of tape feeder setup system 6 according to the embodiment will be described with reference to FIG. 5. In FIG. 5, first tape feeder 5 is exemplified, and second tape feeder 5 is not illustrated. As illustrated in FIG. 5, host computer 7 stores production plan data 73, production result data 74, and device data 75 in attached storage device 72.

Production plan data 73 includes plan information such as the type, the production order, the production quantity. ID information on component mounter 1 to be used, the production start time, and the production end time of boards K to be produced in the future. Production plan data 73 includes a use plan of components P indicating the type and quantity of components P used according to the type of board K. Production plan data 73 is sequentially updated when production of a certain type of board K is completed or when production of new board K is instructed, or periodically updated.

Production result data 74 includes result information such as the type, the production order, the production quantity. ID information on component mounter 1 used, the production start time, and the production end time of boards K produced so far. Production result data 74 includes a use result of component P indicating the type and quantity of component P used according to the type of board K. Production result data 74 is sequentially updated every time production of a certain type of board K is completed, or periodically updated.

Device data 75 includes information related to component mounter 1 and information related to devices such as loading table 32 and tape feeder 5 which are detachably used in component mounter 1. In addition to information related to the performance and the specification of the device, device data 75 includes information related to the operation history and the maintenance history of the device and information related to the current combination status and the past combination history in which the devices are used in combination.

Host computer 7 includes six functional units achieved using software, that is, determination section 91, calculating section 92, estimation section 93, storage section 94, release section 95, and discrimination section 96. Meanwhile, personal computer 83 includes control section 97, which is a functional unit achieved using software, in central processing section 833. Control section 97 acquires ID information read by barcode reader 88. In addition, control section 97 controls feeder control section 59 of tape feeder 5, and provides the operator with setup information by the display on display section 832. Next, each of the functions of the seven functional units will be described.

Determination section 91 refers to at least one of the ID information and device data 75 read by barcode reader 88, and specifies loading table 32, tape feeder 5, component P, carrier tape T. and reel R as a target. In addition, determination section 91 acquires a use plan in the future of component P from production plan data 73. Furthermore, determination section 91 acquires a use frequency in the future of component P that can be estimated from calculating section 92 or estimation section 93. Determination section 91 determines whether to automatically return carrier tape T in the reverse direction of the supply direction based on the use plan in the future of component P and the use frequency in the future of component P that can be estimated for tape feeder 5 placed on loading table 32 as a target. This determination is performed individually for each of multiple tape feeders 5.

Here, calculating section 92 operates in a case where there is a future production plan for multiple types of boards K in production plan data 73. Calculating section 92 calculates the use frequency in the future based on the use plan of components P included in the future production plan of multiple types of boards K. The use frequency in the future is represented by, for example, a fraction in which the total production number of the planned boards K is a denominator and the number of boards K on which components P are mounted is a numerator. Calculating section 92 gives priority to estimation section 93 and transfers the use frequency in the future of component P to determination section 91.

Meanwhile, estimation section 93 operates in a case where there is no future production plan for multiple types of boards K in production plan data 73. That is, estimation section 93 operates only in a case where the type of board K (board type) to be produced next is undetermined or only one board type to be produced next is planned, and calculating section 92 cannot calculate an effective use frequency. Estimation section 93 refers to production result data 74 and estimates a use frequency in the future based on a result use frequency obtained from the use result of component P. Estimation section 93 may set the result use frequency as the use frequency in the future as it is. In addition, estimation section 93 may estimate a use frequency in the future in consideration of the recent tendency of the result use frequency. For example, even when the average result use frequency over a long period is low, it is appropriate for estimation section 93 to estimate a use frequency in the future to be high in a case where the recent use opportunity tends to increase.

Determination section 91 will be further described. Determination section 91 selectively performs the following determinations (1) to (3) on multiple tape feeders 5 placed on loading table 32 as a target so as to correspond to the production of boards K of a previous board type during the setup change for changing the board type to be produced from the previous board type to a next board type.
(1) It is determined that carrier tape T accommodating component P, which is used for the production of board K of the next board type, is not returned in the reverse direction. In this case, tape feeder 5 becomes a first type of tape feeder 5 that supplies component P which is used for the production of board K of the next board type. The operator performs the first setup work of leaving the first type of tape feeder 5 on loading table 32. This means that the first setup work does not involve substantial work.
(2) It is determined that carrier tape T accommodating component P, which is not used for the production of board K of the next board type and in which the use frequency is equal to or greater than a predetermined threshold frequency, is not returned in the reverse direction. The value of the threshold frequency is appropriately set according to the number of available tape feeders 5 or the number of types of planned components P. Qualitatively, the threshold frequency is set to be low when the number of available tape feeders 5 is large and the number of types of components P is small. In this case, tape feeder 5 becomes a second type of tape feeder 5 that supplies component P which is not used for the production of board K of the next board type and in which the use frequency is equal to or greater than the predetermined threshold frequency. The operator performs a second setup work of removing the second type of tape feeder 5 from loading table 32.
(3) It is determined that carrier tape T accommodating component P, which is not used for the production of board K of the next board type and whose use frequency is lower than the threshold frequency, is automatically returned in the reverse direction. In this case, tape feeder 5 becomes a third type of tape feeder 5 that supplies component P which is not used for the production of board K of the next board type and in which the use frequency is lower than the threshold frequency. The operator performs a third setup work of removing the third type of tape feeder 5 from loading table 32 and removing reel R from removed tape feeder 5.

In addition, determination section 91 performs determination instead of (3) for component P of a part of the component types set in advance as a target. That is, determination section 91 determines that carrier tape T accommodating component P, which is not used for the production of board K of the next board type and in which the use frequency is lower than the threshold frequency, is manually returned in the reverse direction. That is, by returning carrier tape T not automatically but manually in the reverse direction, component P can be suppressed from falling off from the region where the cover tape in the vicinity of the leading edge of carrier tape T is peeled off by tape peeling mechanism 56. Normally, expensive component types are set in advance as a part of the component types, and economic loss due to falling off of component P is reduced.

Control section 97 receives any one of the determination results (1) to (3) for each of the tape feeders 5 from determination section 91. In a case where the determination result of determination section 91 is (3), control section 97 causes drive motor 58 (drive mechanism) of tape feeder 5 to return carrier tape T in the reverse direction.

Storage section 94 stores the arrangement position (slot number) of each of multiple tape feeders 5 arranged and placed on loading table 32, the feeder ID for identifying the individual of tape feeder 5, and the reel ID for identifying the individual of reel R in association with each other in device data 75. As a result, the current combination status in which the devices are used in combination with each other is accurately stored.

In a case where carrier tape T is automatically returned in the reverse direction by control section 97, release section 95 releases the association of the arrangement position (slot number), the feeder ID, and the reel ID stored in storage section 94. As a result, the mutual combination status of the devices after the third setup work is performed is accurately stored.

In addition, in a case where tape feeder 5 is removed from loading table 32 without carrier tape T being returned in the reverse direction, release section 95 releases the association with the arrangement position (slot number) while maintaining the association between the feeder ID and the reel ID. As a result, the mutual combination status of the devices after the second setup work is performed is accurately stored.

Discrimination section 96 determines whether there is tape feeder 5 that has fed carrier tape T accommodating components P to be mounted on board K to be produced in the future in the supply direction based on the maintained association between the feeder ID and the reel ID. As a result, it is clear whether tape feeder 5 in which reel R is set and carrier tape T is loaded exists alone. Furthermore, it is determined whether the setup work of tape feeder 5 on reel setting stand 89 is necessary.

### 5. Operation of Tape Feeder Setup System 6

Next, the operation of tape feeder setup system 6 will be described with reference to FIGS. 6 to 12. First, an outline of a production flow for producing multiple types of boards K will be described. As illustrated in FIG. 6, the production flow includes plan creation step MP1, delivery procurement step MP2, setup step MP3, production execution step MP4, post-setup step MP5, and loading step MP6. Tape feeder setup system 6 is used in setup step MP3 and post-setup step MP5. Hereinafter, the description will be made on the assumption that the setup change of second loading table 32 is performed in setup step MP3 when boards K of a current board type are produced using first loading table 32 in production execution step MP4.

In plan creation step MP1, the above-described production plan data 73 is created and updated. In next delivery procurement step MP2, component P to be mounted on board K of the next board type is procured. In a case where component P is in stock, reel R around which carrier tape T accommodating component P is wound is delivered from storage warehouse 79 (refer to arrow A1). Alternatively, tape feeder 5 in which reel R is already set is delivered from storage warehouse 79. In a case where there is no stock of component P or the stock amount is insufficient, component P (reel R) is procured by a method such as purchase.

In next setup step MP3, a setup change of second loading table 32, which is used for the production of boards K of the previous board type and is used, is performed. The operator sets reel R on tape feeder 5 using reel setting stand 89 of external setup station 8 and pulls out carrier tape T from reel R to perform the loading work. Furthermore, the operator places tape feeder 5 on which reel R is set on second loading table 32. The progress of the setup change of second loading table 32 is displayed on display section 832 of personal computer 83.

In next production execution step MP4, when the production of board K of the current board type is completed, first loading table 32 is removed from component mounter 1. Second loading table 32 is attached to component mounter 1, and the production of board K of the next board type is started. Unlike the above description, the setup change for first loading table 32 may be performed after the production of board K of the current board type is completed. Nevertheless, the pause time of component mounter 1 is reduced by alternately using two loading tables 32.

In next post-setup step MP5, post-setup of first loading table 32 is performed. The operator performs the above-described first, second, and third setup works. As a result, the first type of tape feeder 5 is left on first loading table 32. The second type of tape feeder 5 is removed from loading table 32, and a loaded state of the carrier tape and a set state of reel R are maintained. The third type of tape feeder 5 is removed from loading table 32, and reel R is further removed. First loading table 32 in which the first type of tape feeder 5 is left is used in next setup step MP3 (refer to arrow A2).

In next loading step MP6, the operator loads the second type of tape feeder 5 on which reel R is set, the third type of the tape feeder from which reel R is removed, and half-used reel R removed from the third type of the tape feeder into storage warehouse 79 (refer to arrow A3). The operator may temporarily store the second type of tape feeder 5 having a use plan in the near future, for example, inside housing 81 of external setup station 8 without loading tape feeder 5 of the second type.

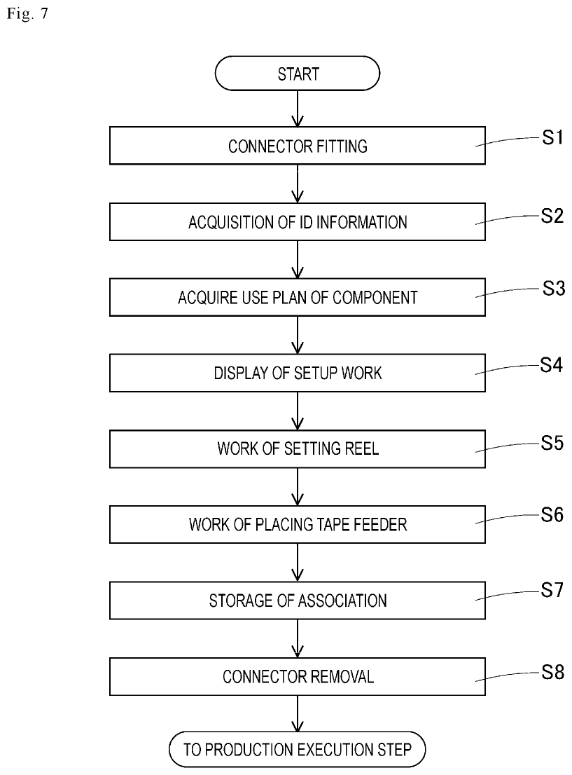

Next, the operation of tape feeder setup system 6 in setup step MP3 will be described together with the work contents of the operator. In step S1 of FIG. 7, the operator moves loading table 32 to the vicinity of external setup station 8 to fit connector 87 into main connector 38. In next step S2, the operator uses barcode reader 88 to read the operation table ID. The operation table ID is transmitted from barcode reader 88 to control section 97. Control section 97 acquires the feeder ID and the reel ID from each of feeder control sections 59 of tape feeders 5 at each arrangement position. The combination of the operation table ID, the arrangement position, the feeder ID, and the reel ID represents the current state of loading table 32.

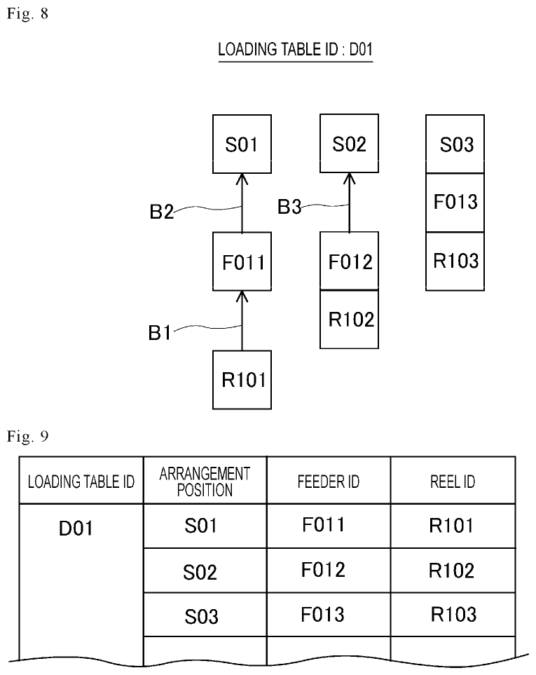

In next step S3, control section 97 acquires a use plan of component P to be used for the next board type from production plan data 73 of host computer 7. In next step S4, control section 97 compares the current state of loading table 32 with the use plan of component P to obtain the shortage of component P. Furthermore, control section 97 displays a setup work required to eliminate the shortage of components P on display section 832 of personal computer 83. Display section 832 performs, for example, the display illustrated in FIG. 8.

In the display example of FIG. 8, the first to third setup works are indicated by arrows B1 to B3. The first setup work indicated by arrow B1 is a work of setting reel R having an ID of “R101” in tape feeder 5 having an ID of “F011”. The second setup work indicated by arrow B2 is a work of placing tape feeder 5 set up in the first setup work at arrangement position S01. The third setup work indicated by arrow B3 is a work of placing tape feeder 5 in which reel R having an ID of “R102” is already set and which has an ID of “F012” at arrangement position S02. The presence or absence of tape feeder 5 in which reel R is already set is determined in advance by discrimination section 96. In addition, regarding arrangement position S03, the first type of tape feeder 5 having an ID of “F013” is placed, and the setup work is unnecessary.

In next step S5, the operator performs the work of setting reel R according to the display of display section 832. For example, in the first setup work described above, the operator first places tape feeder 5 having an ID of “F011” on reel setting stand 89. Next, the operator sets reel R having an ID of “R101” on tape feeder 5 and pulls out carrier tape T from set reel R to perform the loading work. Thereafter, the operator uses barcode reader 88 to read the reel ID. The read reel ID is transferred from control section 97 to feeder control section 59. Feeder control section 59 holds the reel ID and its own feeder ID in association with each other.

In next step S6, the operator performs the work of placing tape feeder 5. For example, in the second setup work described above, the operator places tape feeder 5 having an ID of “F011” at arrangement position S01. In addition, in the third setup work, the operator places tape feeder 5 having an ID of “F012” at arrangement position S02. As the setup work progresses, the display illustrated in FIG. 8 is updated in real time, the completed setup work disappears, and only the remaining setup work is displayed. Therefore, the operator can easily obtain the progress status of the setup work, and an error in the setup work is prevented.

In practice, a large number of setup works for a large number of tape feeders 5 as a target are often performed. In addition, in the second and third setup works described above, the work order is allowed to be changed. On the other hand, the work order of the first and second setup works cannot be changed. The reason is that even when it is tried to set reel R on tape feeder 5 on loading table 32, the work space is small and the setting work is difficult.

In next step S7, storage section 94 associates the ID information and stores the ID information in device data 75. For example, as illustrated in FIG. 9, storage section 94 stores the association of the arrangement position, the feeder ID, and the reel ID using a list format in which each row represents the association. In next step S8, the operator removes connector 87 from main connector 38. As a result, all the setup work for loading table 32 is completed, and the preparation for moving and attaching loading table 32 to component mounter 1 is completed.

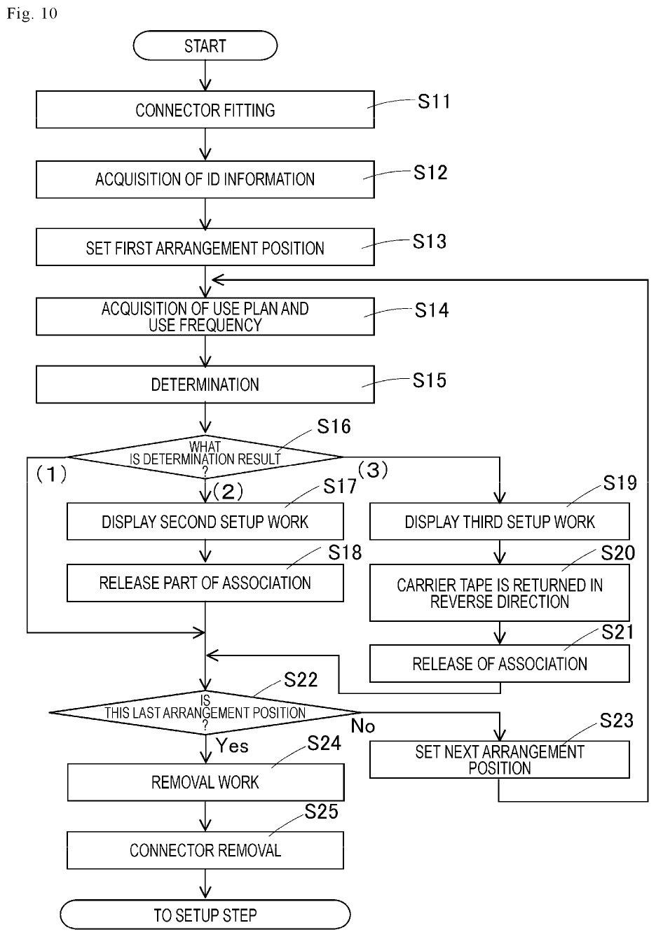

Next, the operation of tape feeder setup system 6 in post-setup step MP5 will be described together with the work contents of the operator. Hereinafter, the description will be made on the assumption that loading table 32 whose current state is illustrated in FIG. 9 is used. In step S11 of FIG. 10, the operator moves used loading table 32 to the vicinity of external setup station 8 to fit connector 87 into main connector 38. In next step S12, similarly to step S2, the operation table ID, the arrangement position, the feeder ID, and the reel ID are acquired. As a result, control section 97 acquires a current state of loading table 32 illustrated in FIG. 9.

In next step S13, determination section 91 sets a first arrangement position (slot number), and focuses on tape feeder 5 placed at the first arrangement position and component P supplied by tape feeder 5. In next step S14, determination section 91 acquires a use plan in the future of component P from production plan data 73. Furthermore, determination section 91 acquires a use frequency in the future of component P from calculating section 92 or estimation section 93.

In next step S15, determination section 91 performs any one of the above-described determinations (1) to (3) regarding whether carrier tape T is automatically returned in the reverse direction of the supply direction. In next step S16, determination section 91 controls the branch destination of the operation flow based on the determination result. That is, corresponding to the determination results (1). (2), and (3), the execution of the operation flow branches to step S22, step S17, and step S19.

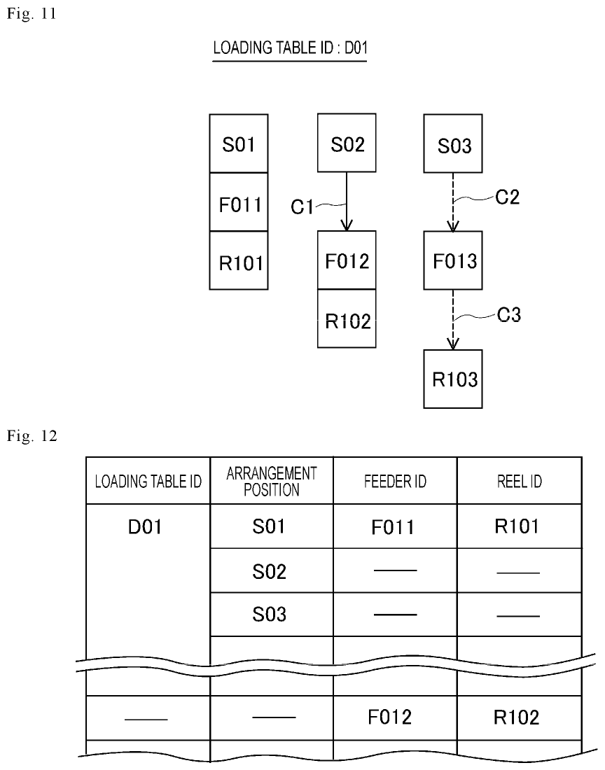

In step S17 in the case where the determination result is (2), display section 832 of personal computer 83 and display section 5B of tape feeder 5 displays that it is the second setup work. For example, display section 832 performs the display illustrated in FIG. 11. In the display example of FIG. 11, the second setup work is indicated by a solid line arrow C1. The second setup work is the work of removing tape feeder 5 having an ID of “F012” from arrangement position S02. In addition, display section 5B of tape feeder 5 displays the second setup work by turning on the orange lamp.

In next step S18, release section 95 releases a part of the association stored in device data 75. That is, although tape feeder 5 is removed from loading table 32, reel R is not removed, and thus release section 95 releases the association with the arrangement position (slot number) while maintaining the association between the feeder ID and the reel ID. As a result, as illustrated in FIG. 12, a field of the feeder ID and a field of the reel ID corresponding to arrangement position S02 are blank (indicated by -). Meanwhile, a row is newly provided in which the loading table ID and the arrangement position are blank, and the feeder ID of “F012” and the reel ID of “R102” are associated with each other. In this manner, discrimination section 96 searches for a row in which two of the feeder ID and the reel ID are associated with each other. After step S18 is executed, the operation flow merges with step S22.

In step S19 in the case where the determination result is (3), display section 832 of personal computer 83 and display section 5B of tape feeder 5 displays that it is the third setup work. For example, in the display example of FIG. 11, the third setup work is indicated by dashed arrows C2 and C3. The third setup work is a work of removing tape feeder 5 having an ID of “F013” from arrangement position S03 (refer to arrow C2) and removing reel R having an ID of “R103” from removed tape feeder 5 (refer to arrow C3). In addition, display section 5B of tape feeder 5 displays the third setup work by turning on the red light.

In next step S20, control section 97 instructs feeder control section 59 to reversely rotate drive motor 58 and causes carrier tape T to be returned in the reverse direction. As a result, the engaged state of carrier tape T with tape feeder 5 is automatically released. In next step S21, release section 95 releases the association stored in device data 75. As a result, as illustrated in FIG. 12, a field of the feeder ID and a field of the reel ID corresponding to arrangement position S03 are blank. After step S21 is executed, the operation flow merges with step S22.

In a case where the determination result is (1), the state where tape feeder 5 is placed on loading table 32 is maintained by the first setup work. Therefore, display section 832 does not display the arrow indicating the work as illustrated in arrangement position S01 of FIG. 11. In addition, none of the three display lamps of display section 5B is lit.

In step S22, determination section 91 determines whether it is the last arrangement position. In step S23 in the case of NO, determination section 91 sets the next arrangement position, changes tape feeder 5 and component P to be focused on, and returns the operation flow to step S14. In a case where it is the last arrangement position in step S22, determination section 91 advances the operation flow to step S24.

In step S24, the operator performs the work of removing tape feeder 5 and reel R corresponding to the second and third setup works. At this time, the contents of the removal work are displayed at two positions, display section 832 and display section 5B. In addition, as the removal work of tape feeder 5 progresses, the display illustrated in FIG. 11 is updated in real time, the completed removal work disappears, and only the remaining removal work is displayed. Therefore, the operator can easily obtain the progress status of the removal work, and an error in the removal work is prevented.

In step S25 after all the removal work is completed, the operator removes connector 87 from main connector 38. As a result, loading table 32 can be stored. The operator may perform next setup step MP3 on loading table 32 without detaching connector 87 from main connector 38.

In tape feeder setup system 6 of the embodiment, it is determined whether carrier tape T is automatically returned in the reverse direction based on the use plan in the future and the use frequency in the future of component P for tape feeder 5 placed on loading table 32 as a target. Therefore, it is possible to select only carrier tape T accommodating component P that is not scheduled to be used, has a low use frequency in the future, and has a low possibility of being used in the near future, and to return carrier tape T in the reverse direction. With this configuration, since the engaged state of carrier tape T with tape feeder 5 is automatically released, the labor of the setup change for removing reel R is reduced. In addition, it is possible to effectively use owned tape feeder 5 the number of which is limited.

On the other hand, carrier tape T accommodating component P which has a high use frequency in the future and is likely to be used in the near future even when component P is not scheduled to be used is maintained in a loaded state into tape feeder 5. With this configuration, double labor for the resetting work of reel R and the reloading work of carrier tape T in the near future is not necessary, and the labor of the setup change is reduced. In addition, since the total number of times of the setting work and the removal work of reel R is reduced, it is possible to reduce the loss of components P that fall off from carrier tape T with the work.

### 6. Application and Modification of Embodiment

The sharing of functions between host computer 7 and personal computer 83 can be changed in various manners. For example, seven functional units may be integrated with personal computer 83, and host computer 7 may be omitted. In addition, one of calculating section 92 and estimation section 93 may be omitted. Furthermore, the display method of display section 832 of personal computer 83 and display section 5B of tape feeder 5 can be changed in various manners. In addition, only one of display section 832 and display section 5B may perform display. Various modifications can be made to the configuration of tape feeder 5. For example, the present embodiment can also be applied to a reel separate type configuration in which reel R is disposed outside tape feeder 5. In addition, the embodiments can be applied or modified in various manners.

### REFERENCE SIGNS LIST

1: component mounter. 2: board conveyance section. 3: component supply section. 32: loading table. 4: component transfer section. 5: tape feeder. 57: sprocket. 58: drive motor. 59: feeder control section. 5B: display section. 6: tape feeder setup system. 7: host computer. 73: production plan data. 74: production result data. 75: device data. 8: external setup station. 83: personal computer. 832: display section. 88: barcode reader. 89: reel setting stand. 91: determination section. 92: calculating section. 93: estimation section. 94: storage section. 95: release section. 96: discrimination section. 97: control section. K: board. R: reel. T: carrier tape. P: component

1. A tape feeder setup system comprising:
a loading table on which a tape feeder is placed, the tape feeder having a drive mechanism configured to feed a carrier tape accommodating multiple components to be mounted on a board from a reel in a predetermined supply direction and supplying the component;
a determination section configured to determine whether the carrier tape is automatically returned in a reverse direction of the supply direction based on a use plan in a future of the component and an estimable use frequency in the future of the component for the tape feeder placed on the loading table as a target; and
a control section configured to cause the drive mechanism of the tape feeder to return the carrier tape in the reverse direction in a case where the determination section determines that the carrier tape is automatically returned in the reverse direction.

2. The tape feeder setup system according to claim 1, further comprising:
a calculating section configured to calculate the use frequency in the future based on the use plan of the component included in a future production plan of multiple types of boards.

3. The tape feeder setup system according to claim 1, further comprising:
an estimation section configured to estimate a use frequency in the future based on a result use frequency obtained from a use result of the component.

4. The tape feeder setup system according to claim 1, wherein
the determination section and the control section operate on multiple tape feeders placed on the loading table as a target so as to correspond to production of the board of a previous board type during a setup change of changing a type of the board to be produced from the previous board type to a next board type.

5. The tape feeder setup system according to claim 4 wherein
the determination section
determines that the carrier tape accommodating the component, which is used for production of the board of the next board type, is not returned in the reverse direction,
determines that the carrier tape accommodating the component, which is not used for the production of the board of the next board type and in which the use frequency is equal to or greater than a predetermined threshold frequency, is not returned in the reverse direction, and
determines that the carrier tape accommodating the component, which is not used for the production of the board of the next board type and in which the use frequency is lower than the threshold frequency, is automatically returned in the reverse direction.

6. The tape feeder setup system according to claim 5, wherein
the determination section determines that the carrier tape accommodating the component, which is not used for the production of the board of the next board type and in which the use frequency is lower than the threshold frequency, is manually returned in the reverse direction for the component of a part of component types set in advance as a target.

7. The tape feeder setup system according to claim 4, further comprising:
a display section configured to display types of a first type of the tape feeder supplying the component which is used for production of the board of the next board type,
a second type of the tape feeder supplying the component which is not used for the production of the board of the next board type and in which the use frequency is equal to or greater than a predetermined threshold frequency, and
a third type of the tape feeder supplying the component which is not used for the production of the board of the next board type and in which the use frequency is lower than the threshold frequency.

8. The tape feeder setup system according to claim 4, further comprising:
a display section configured to display a work distinction between
a first setup work of leaving the tape feeder supplying the component, which is used for production of the board of the next board type, on the loading table,
a second setup work of removing the tape feeder supplying the component, which is not used for the production of the board of the next board type and in which the use frequency is equal to or greater than a predetermined threshold frequency, from the loading table, and
a third setup work of removing the tape feeder supplying the component, which is not used for the production of the board of the next board type and in which the use frequency is lower than the threshold frequency, from the loading table, and further removing the reel from the removed tape feeder.

9. The tape feeder setup system according to claim 7, wherein
the display section is provided in each of the multiple tape feeders.

10. The tape feeder setup system according to claim 1, wherein
the loading table is attachable to and detachable from a component mounter mounting the component on the board, and is attachable to and detachable from an external setup station including the control section or communicably connected to the external setup station.

11. The tape feeder setup system according to claim 1, further comprising:
a storage section configured to store an arrangement position of each of the multiple tape feeders arranged and placed on the loading table, a feeder ID for identifying an individual of the tape feeder, and a reel ID for identifying an individual of the reel in association with each other; and
a release section configured to release an association of the arrangement position, the feeder ID, and the reel ID stored in the storage section in a case where the carrier tape is automatically returned in the reverse direction by the control section, and release an association of the arrangement position while maintaining an association of the feeder ID and the reel ID in a case where the tape feeder is removed from the loading table without the carrier tape being returned in the reverse direction.

12. The tape feeder setup system according to claim 11, further comprising:
a discrimination section configured to determine whether there is the tape feeder that has fed the carrier tape accommodating the component to be mounted on the board to be produced in the future in the supply direction based on the maintained association between the feeder ID and the reel ID.
